(19) United States
(12) Patent Application Publication
(10) Pub. No.: US 2011/0007488 A1
(43) Pub. Date: Jan. 13, 2011

(54) POWER SUPPLY CURRENT CIRCUIT STRUCTURE

(76) Inventor: Chin-Wei LIU, Taoyuan City (TW)

Correspondence Address: Muncy, Geissler, Olds & Lowe, PLLC, 4000 Legato Road, Suite 310, FAIRFAX, VA, 22033, US

(21) Appl. No.: 12/498,640

(22) Filed: Jul. 7, 2009

(51) Int. Cl. H05K 7/00

(52) U.S. Cl. 361/767

(57) ABSTRACT

The present invention discloses a power supply current circuit structure including: a conducting plate device, made of an electrically conducting material, and including a plurality of separated conducting plates, a plurality of insert holes disposed on the conducting plates, and each conducting plate having a polarity opposite to the polarity of an adjacent conducting plate; an insulating layer, fixed onto the conducting plate device, and made of a non-conductive material; an electronic component module, installed on the insulating layer, and including a plurality of electronic components, each having two insert pins passed through the insulating layer and inserted into the insert holes of the adjacent conducting plate to constitute a current path. The invention provides a convenient and economic way of manufacturing a printed circuit board with a large current path and achieves the effect of preventing related electronic components from being damaged.

### BACKGROUND OF THE INVENTION

1. Field of the Invention

The present invention relates to a power circuit structure, in particular to a power supply current circuit structure that can reduce the installation area of a printed circuit board and achieve the effects of providing a simple and easy manufacture, saving manpower, and assuring the safety of electronic components.

2. Description of the Related Art

As all present existing computers come with a power supply for converting 110VAC or 220VAC power inputted from an external cable into 12VDC or ±5VDC power required by hardware equipments including a main board, a hard disk, and an optical disk drive, etc. The power supply includes a printed circuit board provided for installing or inserting a plurality of electronic components directly. Particularly, a high-power electronic component (such as a capacitor) has to take the requirements of passing a large current and heat dissipation into consideration, and thus the area of the printed circuit board cannot be reduced effectively, and it constitutes a limitation of it's application to products with a light, thin, short and compact design. To overcome this problem, the existing technologies still erect some of the electronic components on the printed circuit board as shown in FIG. 1. The conventional power supply current circuit structure includes a printed circuit board 90, and the printed circuit board 90 includes electronic components (not shown in the figure) and a sub-circuit board 91, and the sub-circuit board 91 includes local electronic components 92 installed thereon, and if the local electronic components 92 are electronic components requiring the supply of a large current, the sub-circuit board 91 must be thickened and broadened by repeated soldering processes to form a large current path 93, such that the large current path 93 provides the large current requirement to the local electronic components 92.

Although the aforementioned existing power supply current circuit structure can maximize the utility of space or reduce the area and space of the power supply, yet the large current path 93 formed by the repeated soldering method (to thicken and broaden the sub-circuit board) may burn the electronic components installed on the sub-circuit board 91 due to overheat or cause a low performance, and the repeated soldering process also has the shortcomings of increasing the manpower, giving an ugly appearance of the product to damage the product image, and failing to comply with the environmental protection requirement of minimizing the soldering operation. Therefore, it is an important subject for designers and manufacturers of the related industry to improve the existing power supply current circuit structure and overcome the shortcomings of the prior art.

In view of the shortcomings of the conventional printed circuit board, the inventor of the present invention conducted extensive researches and experiments, and finally developed a power supply current circuit structure that can reduce the installation area of a printed circuit board and achieve the effects of providing a simple and easy manufacture, saving manpower, and assuring the safety of electronic components.

### SUMMARY OF THE INVENTION

Therefore, it is a primary objective of the present invention to provide a power supply current circuit structure for facilitating the manufacture of a printed circuit board with a large current path in a more convenient and economic way and preventing related electronic components from being damaged to assure the quality, stability and safety of the electronic components, and improve the product competitiveness.

To achieve the foregoing objective, the present invention provides a power supply current circuit structure comprising: a conducting plate device, being made of an electrically conducting material and including a plurality of conducting plates, a plurality of insert holes disposed on the conducting plate, and each insert hole having a polarity opposite to the polarity of an adjacent conducting plate; an insulating layer, fixed onto the conducting plate device, and made of a non-conductive material; an electronic component module, installed onto the insulating layer, and including a plurality of electronic components, and the electronic components including two insert pins passed through the insulating layer and connected to the insert hole of the adjacent conducting plate to form a current path.

The insulating layer can be a non-conducting plate, and includes a plurality of insert holes corresponding to the insert holes of the conducting plate respectively, and the insert holes of the insulating layer are provided for passing the insert pins of electronic components and connecting the insert pins to the insert holes of the adjacent conducting plate to form a current path.

The insulating layer can be formed by coating a non-conductive thermal insulating sol-gel coating onto the conducting plate, such that when the electronic components are inserted and installed to the conducting plate, the insulating layer is provided for achieving the insulation effect between the adjacent conducting plates.

To make it easier for our examiner to understand the objective of the invention, its structure, innovative features, and performance, we use a preferred embodiment together with the attached drawings for the detailed description of the invention.

### BRIEF DESCRIPTION OF THE DRAWINGS

FIG. 1 is a schematic view of a conventional power supply current circuit structure;

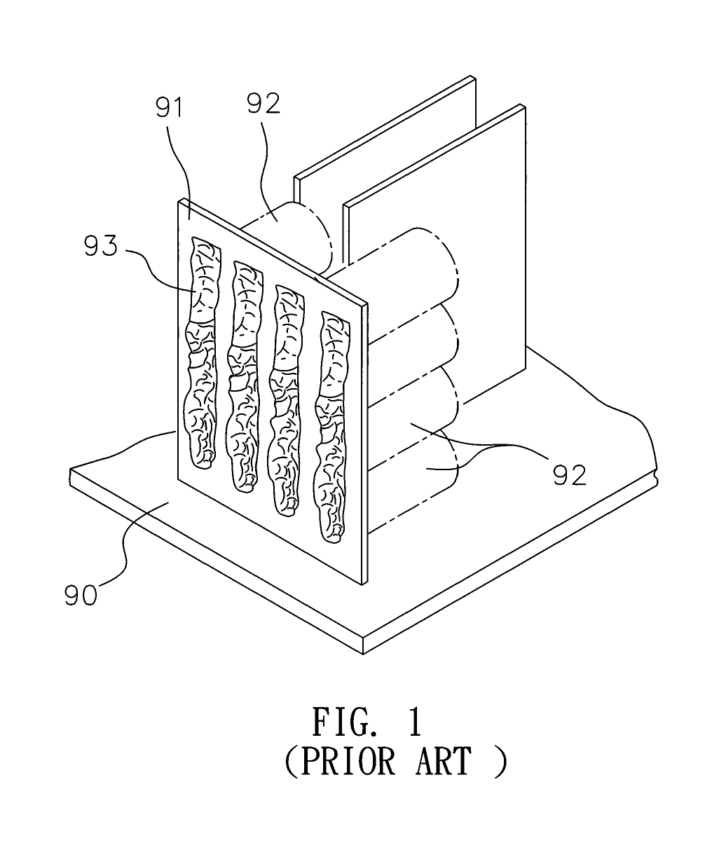

FIG. 2 is a schematic view of a power supply current circuit in accordance with a first preferred embodiment of the present invention;

FIG. 3 is an exploded view of a power supply current circuit in accordance with a first preferred embodiment of the present invention;

FIG. 4 is a bottom cross-sectional view of a power supply current circuit in accordance with a first preferred embodiment of the present invention;

FIG. 5 is a schematic view of installing a power supply current circuit in accordance with a first preferred embodiment of the present invention; and

FIG. 6 is a schematic view of a power supply current circuit in accordance with a second preferred embodiment of the present invention.

### DETAILED DESCRIPTION OF THE PREFERRED EMBODIMENTS

The present invention will now be described in more detail hereinafter with reference to the accompanying drawings that show various embodiments of the invention as follows.

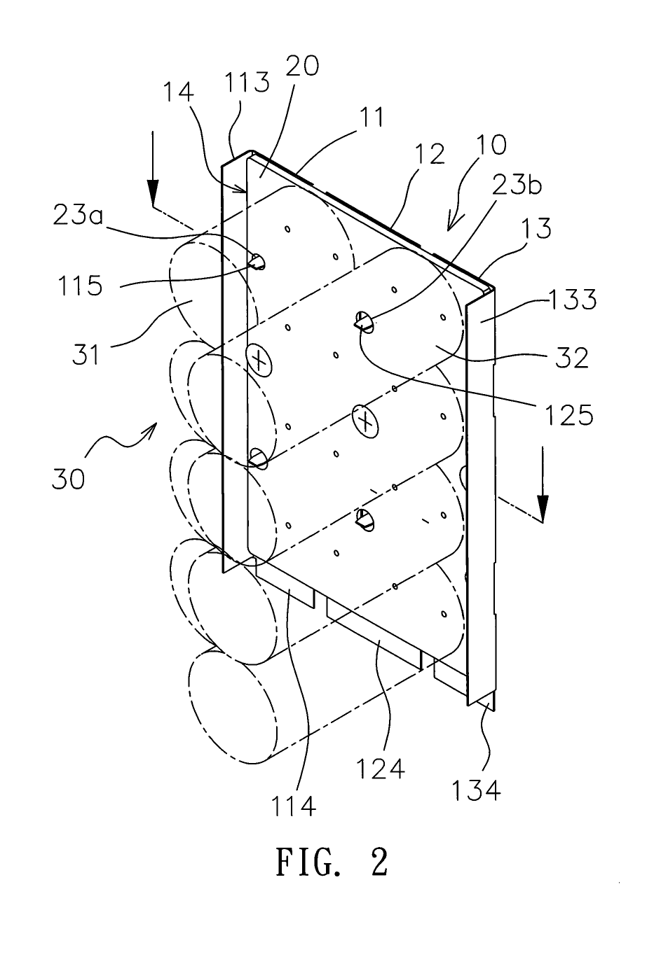

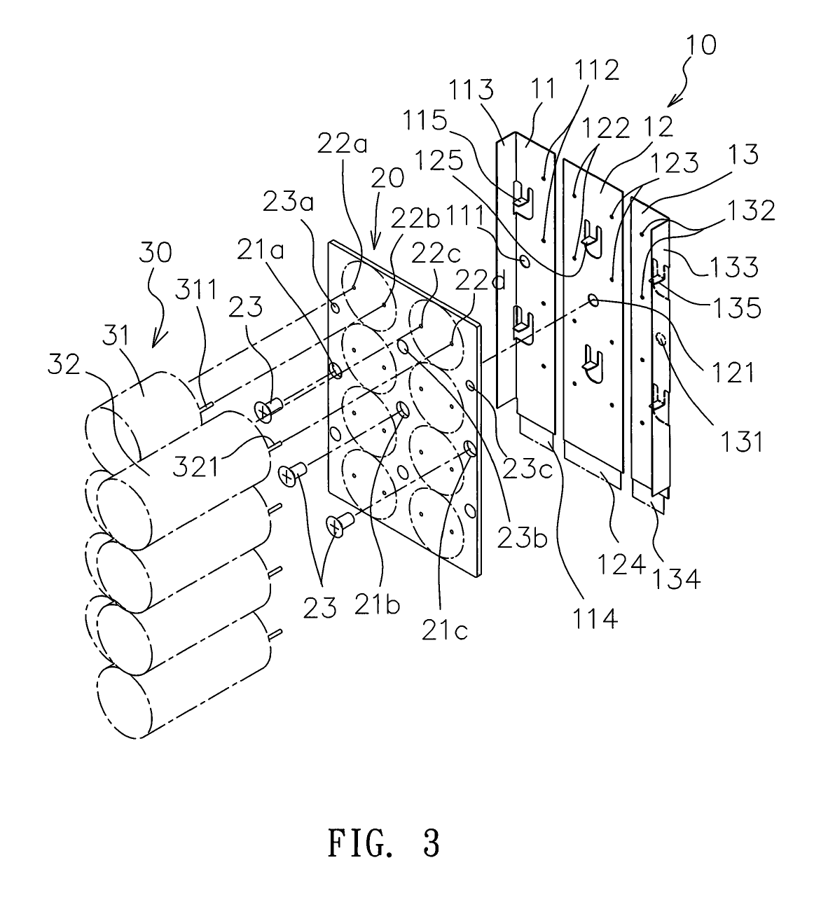

With reference to FIGS. 2 and 3 for a power supply current circuit structure in accordance with a first preferred embodiment of the present invention, the power supply current circuit structure comprises a conducting plate device 10, an insulating layer 20 and an electronic component module 30, wherein the conducting plate device 10 is made of an electrically conducting material or a metal conducting plate (such as a copper plate), and includes a first conducting plate 11, a second conducting plate 12 and a third conducting plate 13 arranged sequentially, and each of the first conducting plate 11, second conducting plate 12 and third conducting plate 13 has a fixing hole 111, 121, 131 disposed thereon and an electrode plate 114, 124, 134 disposed at the bottom of the conducting plates, and each of the first conducting plate 11 and the third conducting plate 13 has a plurality of insert holes 112, 132 arranged longitudinally and terminal plates 113, 133 formed by being a distal edge of the plates 11, 13, and the terminal plates 113, 133 define a retaining space 14 of the conducting plate device 10, and the second conducting plate 12 includes two rows of insert holes 122, 123 arranged longitudinally, and the first conducting plate 11, the second conducting plate 12, the third conducting plate 13 are stamped to form a plurality of positioning plates 115, 125, 135.

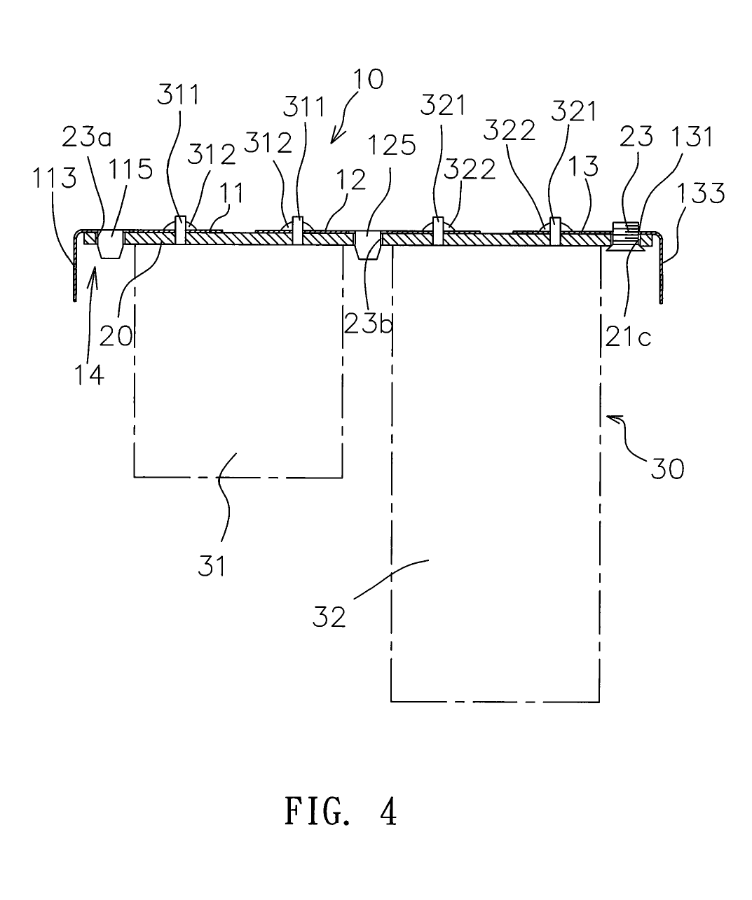

The insulating layer 20 is made of a non-conductive material (wherein the insulating layer 20 is a sheet in a specific shape in this preferred embodiment), but persons skilled in the art can coat a non-conductive thermal insulating sol-gel coating on the conducting plate device to achieve the insulating layer 20 as well), and a plurality of fixing hole 21a, 21b, 21c are disposed on the insulating layer 20 and corresponding to the fixing holes 111, 121, 131, a plurality of insert holes 22a, 22b, 22c, 22d correspond to the insert holes 112, 122, 123, 132, and a plurality of positioning hole 23a, 23b, 23c correspond to the positioning plate 115, 125, 135 respectively. With reference to FIG. 4 together for the assembling, the positioning plates 115, 125, 135 of the first conducting plate 11, the second conducting plate 12, the third conducting plate 13 are passed into the positioning holes 23a, 23b, 23c of the insulating layer 20 respectively, such that the first conducting plate 11, the second conducting plate 12 and the third conducting plate 13 are fixed onto the insulating layer 20, and the insulating layer 20 is installed at the retaining space 14 of the conducting plate device 10 and a screw 23 is passed through the fixing holes 21a, 21b, 21c of the insulating layer 20 and the fixing holes 111, 121, 131 of the first conducting plate 11, the second conducting plate 12 and the third conducting plate 13 are connected by screws, such that the first conducting plate 11, the second conducting plate 12, the third conducting plate 13 are installed separately and fixed with the insulating layer 20 integrally, so as to form a current circuit board for installing related electronic components.

The electronic component module 30 is installed on the insulating layer 20 and includes a plurality of first electronic components 31 and second electronic components 32 that require a supply of large current, and each of the first electronic components 31 and the second electronic components 32 includes two insert pins 311, 321. When the electronic component module 30 is installed, the two insert pins 311 of each first electronic component 31 are inserted into the insert hole 22a of the insulating layer 20 and the insert hole 112 of the first conducting plate 11, and the insert hole 22b of the insulating layer 20 and the insert hole 122 of the second conducting plate 12 respectively, and the two insert pins 321 of the second electronic components 32 are inserted into the insert hole 22c of the insulating layer 20 and the insert hole 123 of the second conducting plate 12 and the insert hole 22d of the insulating layer 20 and the insert hole 132 of the third conducting plate 13 respectively, and the insert pin 311 at the rear end of the insert hole 112, 122 and the insert pin 321 at the rear end of insert hole 123, 132 are provided for connecting a circuit by a local spot soldering, so as to complete installing the electronic component module 30.

The conducting plate device 10 is configured with an appropriate electrode polarity. For example, the first conducting plate 11 and the third conducting plate 13 are set as anodes, and the second conducting plate 12 is set as a cathode, such that the two insert pins 311 of the first electronic component 31 are connected to the anode and the cathode respectively, and the two insert pins 321 of the second electronic components 32 are connected to the cathode and the anode respectively. Of course, if the first conducting plate 11 and the third conducting plate 13 are set as cathodes, then the second conducting plate 12 is set as an anode. Similarly, the two insert pins 311 of the first electronic components 31 and the second electronic components 32 are connected between the anode and the cathode to complete the connection for passing currents. In the meantime, the first conducting plate 11, the second conducting plate 12 and the third conducting plate 13 are provided for passing a large current, so that the repeated soldering processes for thickening and broadening the sub-circuit to produce a large current path as required by the conventional printed circuit board are no longer needed, and such arrangement can simplify the manufacture and assure the safety of electronic components.

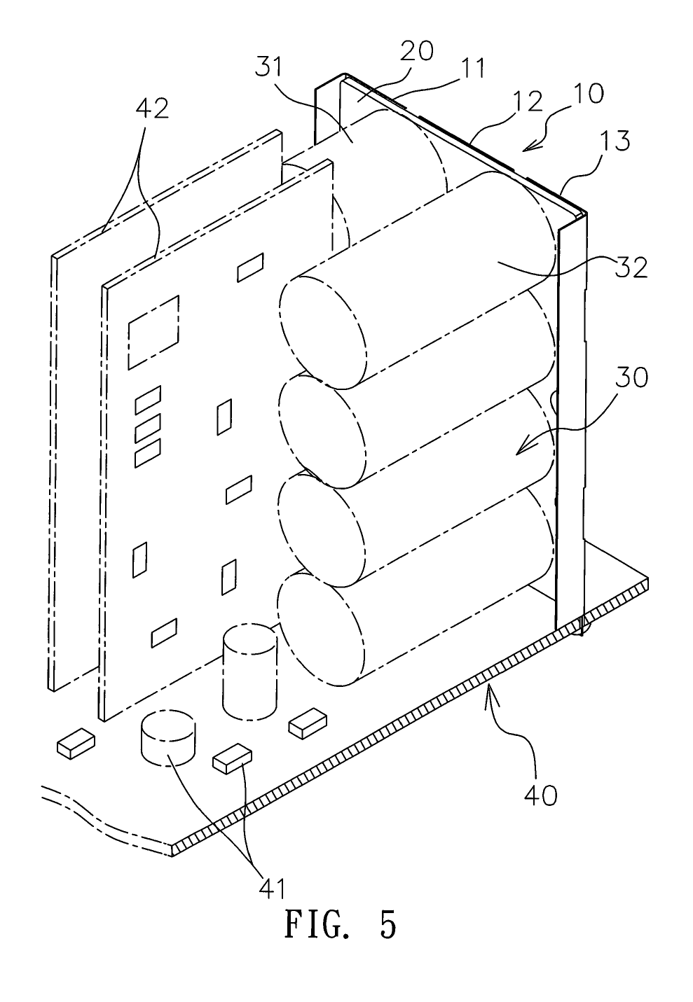

With reference to FIG. 5 together for applying a power supply current circuit structure to a printed circuit board 40 installed in a power supply in accordance with the present invention, the printed circuit board 40 includes a plurality of electronic components 41 and a sub-circuit board 42, such that the electrode plates 114, 124, 134 of the conducting plate device 10 (including the first conducting plate 11, the second conducting plate 12 and the third conducting plate 13) are inserted and fixed to predetermined positions (not shown in the figure) of the printed circuit board 40 to complete the connection of a circuit, and allow a large current to pass through.

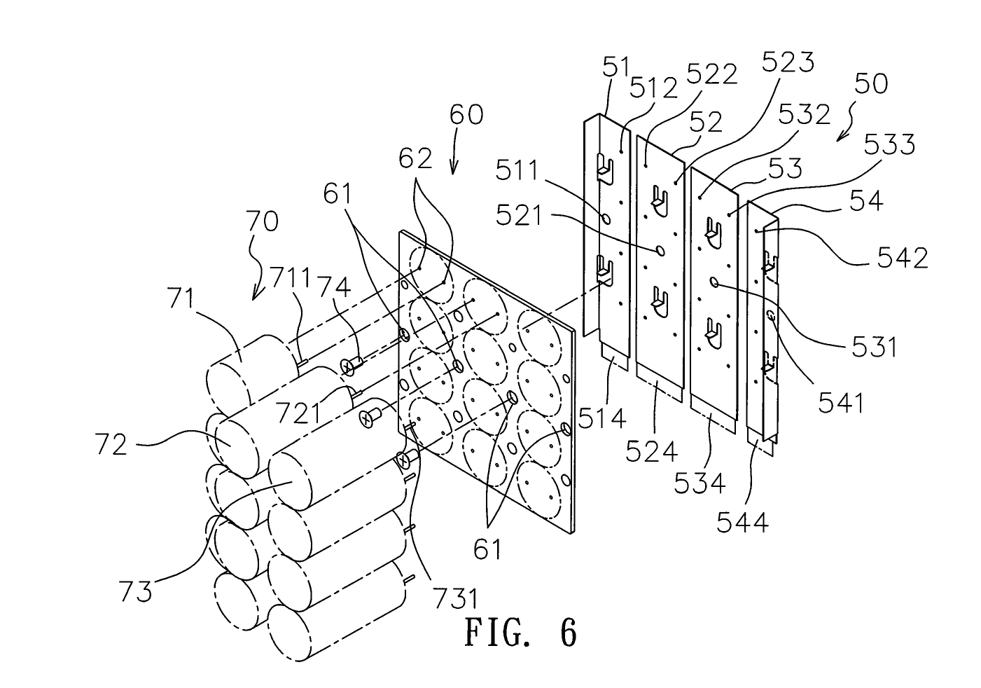

With reference to FIG. 6 for a power supply current circuit structure in accordance with a second preferred embodiment of the present invention, a broader application is provided, based on the structure of the first preferred embodiment, wherein the conducting plate device 50 includes a first conducting plate 51, a second conducting plate 52, a third conducting plate 53 and a fourth conducting plate 54 installed sequentially, and the electronic component module 70 includes a plurality of first electronic components 71, second electronic components 72 and third electronic components 73 that require a supply of a large current. Similarly, an insulating layer 60 is passed through a fixing hole 61 by a screw 74 and whose corresponding fixing holes 511, 521, 31, 541 is provided for screwing and connecting the first conducting plate 51, the second conducting plate 52, the third conducting plate 53 and the fourth conducting plate 54, such that the first conducting plate 51, the second conducting plate 52, the third conducting plate 53 and the fourth conducting plate 54 are separated to form a current circuit board, and then an insert hole 62 of the insulating layer 60 is provided for connecting two insert pins 711 of the first electronic components 71 with an insert hole 512 of the first conducting plate 51, and an insert hole 522 of the second conducting plate 52 respectively, and two insert pins 721 of the second electronic components 72 are connected to an insert hole 523 of the second conducting plate 52 and an insert hole 532 of the third conducting plate 53, and two insert pins 731 of the third electronic components 73 are connected to an insert hole 533 of the third conducting plate 53 and an insert hole 542 of the fourth conducting plate 54, and each insert pin 711, 721, 731 is fixed by a local spot soldering process. Finally, electrode plates 514, 524, 534, 544 of the first conducting plate 51, the second conducting plate 52, the third conducting plate 53 and the fourth conducting plate 54 are inserted and fixed to predetermined positions (not shown in the figure) of a printed circuit board to complete the connection of a circuit and allow a large current to pass through.

The conducting plate device 50 is configured with an appropriate electrode polarity. For example, the first conducting plate 51 and the third conducting plate 53 are set as anodes, and the second conducting plate 52 and the fourth conducting plate 54 are set as cathodes, so that the two insert pins 711 of the first electronic components 71 are connected to the anode and the cathode respectively, and the two insert pins 721 of the second electronic components 72 are connected to the cathode and the anode respectively, and the two insert pins 731 of the third electronic components 73 are connected to the anode and the cathode. Of course, the first conducting plate 51, the second conducting plate 52, the third conducting plate 53 and the fourth conducting plate 54 can be arranged in a cathode-anode-cathode-anode sequence to complete the current path. Similarly, the repeated soldering processes performed to the printed circuit board can be waived, and the space and capacity of installing electronic components can be increased.

In summation of the description, the present invention improves over the prior art and complies with the patent application requirements, and thus is filed for patent application. While the invention has been described by means of specific embodiments, numerous modifications and variations could be made thereto by those skilled in the art without departing from the scope and spirit of the invention set forth in the claims.

What is claimed is:

1. A power supply current circuit structure, comprising:
a conducting plate device, made of an electrically conducting material, and including a plurality of separated conducting plates, a plurality of insert holes disposed on said conducting plates, and each conducting plate having a polarity opposite to the polarity of an adjacent conducting plate;
an insulating layer, fixed onto said conducting plate device, and made of a non-conductive material;
an electronic component module, installed on said insulating layer, and including a plurality of electronic components, each having two insert pins passed through said insulating layer and inserted into said insert holes of an adjacent conducting plate to constitute a current path.

2. The power supply current circuit structure according to claim 1, wherein said conducting plate is a copper plate.

3. The power supply current circuit structure according to claim 1, wherein said insulating layer is a sheet with a specific shape, and said insulating layer includes a plurality of insert holes corresponding to said insert holes of said conducting plate respectively.

4. The power supply current circuit structure according to claim 3, wherein said conducting plate includes at least one fixing hole, and said insulating layer includes a fixing hole corresponding to said fixing hole of said conducting plate and fixed by a screw.

5. The power supply current circuit structure according to claim 1, wherein said conducting plate includes an electrode plate disposed at the bottom of said conducting plate and provided for inserting onto a printed circuit board.

6. The power supply current circuit structure according to claim 1, wherein said conducting plate disposed at a distal end of said conducting plate device includes a terminal plate with formed by a retaining space formed by bending an external distal edge of said conducting plate.

7. The power supply current circuit structure according to claim 3, wherein said conducting plate includes a positioning plate stamped from said conducting plate, and said insulating layer includes a positioning hole corresponding to said positioning plate.

8. The power supply current circuit structure according to claim 1, wherein said electronic components are electronic components passed with a large electric current.

9. The power supply current circuit structure according to claim 1, wherein said insert pin and said insert hole at a rear end of said conducting plate adopt a local spot soldering.

10. The power supply current circuit structure according to claim 1, wherein said conducting plate device includes a first conducting plate, a second conducting plate and a third conducting plate installed and arranged with an anode-cathode-anode sequence or a cathode-anode-cathode sequence.

11. The power supply current circuit structure according to claim 1, wherein said conducting plate device includes a first conducting plate, a second conducting plate, a third conducting plate and a fourth conducting plate installed and arranged in an anode-cathode-anode-cathode sequence or a cathode-anode-cathode-anode sequence.

12. The power supply current circuit structure according to claim 1, wherein said insulating layer is made of a non-conductive thermal insulating gel, and formed onto said conducting plates by a coating method.
